(19) United States
(12) Patent Application Publication
(10) Pub. No.: US 2009/0301766 A1
(43) Pub. Date: Dec. 10, 2009

(54) Printed circuit board including electronic component embedded therein and method of manufacturing the same

(75) Inventors: Hwa Sun Park, Gyunggi-do (KR); Yul Kyo Chung, Gyunggi-do (KR); Jin Won Lee, Seoul (KR); Jin Soo Jeong, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/219,441

(22) Filed: Jul. 22, 2008

(30) Foreign Application Priority Data
Jun. 4, 2008 (KR) 10 -2008-0052675

(51) Int. Cl. H05K 1/03; H01R 43/00

(52) U.S. Cl. 174/255; 29/855

(57) ABSTRACT

Disclosed herein is a printed circuit board including an electronic component embedded therein, as the electronic component is supported on the metal layer of core substrate, thus supporting and radiation performances are improved, production costs are reduced, and the manufacturing process is simplified.

### CROSS REFERENCE TO RELATED APPLICATION

This application claims the benefit of Korean Patent Application No. 10-2008-0052675, filed Jun. 4, 2008, entitled “PRINTED CIRCUIT BOARD INCLUDING ELECTRONIC COMPONENT EMBEDDED THEREIN AND METHOD FOR MANUFACTURING THE SAME”, which is hereby incorporated by reference in its entirety into this application.

### BACKGROUND OF THE INVENTION

1. Field of the Invention

The present invention relates generally to a printed circuit board including an electronic component embedded therein and a method of manufacturing the same, and, more particularly, to a printed circuit board including an electronic component embedded therein and a method of manufacturing the same, which enables an electronic component to be embedded therein without using tape.

2. Description of the Related Art

These days, in response to the miniaturization and the increase in the functionality of electronic products, printed circuit boards, which include electronic components embedded therein, are getting a lot of attention.

In order to realize a printed circuit board including electronic components embedded therein, there exists a wide variety of surface-mounting technologies for mounting semiconductor devices such as Integrated Circuit (IC) chips on a printed circuit board. The surface-mounting technologies may include a wire bonding technology and a flip chip technology.

Among these, a surface-mounting process using the wire bonding technology is configured in a manner such that an electronic component, on which a designed circuit is printed, is bonded on a printed circuit board using adhesive, terminals (i.e., pads) of the electronic component are connected to lead frames of the printed circuit board via metal wires for the transmission of information therebetween, and the electronic component and the wires are molded by using thermosetting resin or thermoplastic resin.

Meanwhile, a surface-mounting process using the flip chip technology is configured in a manner such that external connecting terminals (i.e., bumps) having a size ranging from several μm to hundreds of μm are formed on an electronic component using connecting materials such as gold, solder and other metals, the electronic component including the bump formed thereon is flipped over so that the surface of the component faces a printed circuit board, and the electronic component is mounted on the printed circuit board in the flipped orientation, unlike the process using the wire bonding technology.

Since these surface-mounting processes are conducted in a common manner in which electronic component is mounted on the surface of a printed circuit board, the total thickness of the resulting product after the mounting process cannot be less than the sum of thicknesses of the printed circuit board and the electronic component, thus making the manufacture of a high-density product difficult. In addition, since electrical connection between the electronic component and the printed circuit board is achieved using the connecting terminals (pads or bumps), the electrical connection may be damaged or may malfunction due to breakage or corrosion of the connecting terminals, thus deteriorating the reliability of the product.

For this reason, in order to overcome the above problems, electronic components are embedded inside rather than outside the printed circuit, and a build-up layer is formed for the electrical connection, thereby realizing compact and high-density products, minimizing a wiring distance at a high frequency (100 MHz or higher), and avoiding the deterioration in reliability occurring at a stage of connecting components to each other in the surface-mounting process using the wire bonding technology or the flip chip technology.

FIGS. 1 to 7 are cross-sectional views showing a conventional process of manufacturing a printed circuit board including an electronic component embedded therein.

Referring to the drawings, the conventional process is now described.

First, as shown in FIG. 1, a core substrate 10, which is comprised of a copper clad laminate and an internal circuit layer 11 formed on the copper clad laminate, in which a cavity 12 for receiving an electronic component therein is formed in the copper clad laminate, is prepared.

As shown in FIG. 2, tape 13, which serves to support an electronic component, is attached to one side of the core substrate 10.

As shown in FIG. 3, an electronic component 14 having electrode terminals 15 thereon is inserted in the cavity 12, and is then attached to the tape 13 in a face-up orientation.

As shown in FIG. 4, thereafter, a first insulating layer 16 is formed on the other side of the core substrate 10 on which the tape 13 is not attached, and is also formed in a gap between the electronic component 14 and the inner wall of the cavity 12.

As shown in FIG. 5, the tape 13 is removed from the one side of the core substrate 10.

As shown in FIG. 6, a second insulating layer 17 is formed on the other side of the core substrate 10 from which the tape 13 is removed.

As shown in FIG. 7, finally, an external circuit layer 18, which has vias 19 connected to the internal circuit layer 11 or the electrode terminals 15 of the electronic component 14, is formed on the first insulating layer 16 and the second insulating layer 17.

However, the conventional process of manufacturing the printed circuit board including an electronic component embedded therein, as shown in FIGS. 1 to 7, has problems in that since the tape 13 for supporting the electronic component 14 is used only in the manufacturing process, production costs are inevitably increased, and the manufacturing process is complicated due to the taping process of attaching and detaching the tape 13.

In addition, since the manufacturing process is conducted in a manner such that the electronic components 14 are supported on the tape 13, the first insulating layer 16 is formed on the other side of the core substrate 10 on which the tape 13 is not attached, the tape 13 is removed, and the second insulating layer 17 is attached to the one side of the core layer 10 from which the tape 13 is removed, the production time is disadvantageously prolonged.

### SUMMARY OF THE INVENTION

Accordingly, the present invention has been made keeping in mind the above problems occurring in the prior art, and the present invention provides a printed circuit board including an electronic component embedded therein, which can be simply manufactured without using tape, and a method of manufacturing the printed circuit board.

In one aspect, the present invention provides a printed circuit board including an electronic component embedded therein, including: a core substrate, which includes an insulating resin layer having a cavity formed therein, a metal support layer formed on one side of the insulating resin layer and internal circuit layers formed on both sides of the insulating resin layer; an electronic component received in the cavity while being supported on the metal support layer; and build-up layers, which include insulating layers and external circuit layers formed on both sides of the core substrate.

The electronic component may be mounted in a face-up orientation.

The electronic component may be fixed on the metal support layer using adhesive material.

The adhesive material may be a silicone rubber plate or a polyimide adhesive tape.

The external circuit layers may include vias connected to electrode terminals of the electronic component or the internal circuit layers.

In another aspect, the present invention provides a method of manufacturing a printed circuit board including an electronic component embedded therein, including: preparing a core substrate, which includes an insulating resin layer having a cavity formed therein, a metal support layer formed on one side of the insulating resin layer and internal circuit layers formed on both sides of the insulating resin layer; mounting an electronic component in the cavity such that the electronic component is supported on the metal support layer; and forming build-up layers, which include insulating layers and external circuit layers, on both sides of the core substrate.

The preparing the core substrate may include: forming a through-hole in a double-sided copper clad laminate and subjecting the through-hole to metal plating; removing a portion of the insulating resin layer and a portion of a metal layer formed on one side of the insulating resin layer, thus forming the cavity; and patterning the metal layer while leaving a metal layer formed on the other side of the insulating resin layer, thus forming the metal support layer and the internal circuit layers.

In the mounting the electronic component, the electronic component may be mounted in a face-up orientation.

In the mounting the electronic component, the electronic component may be fixed on the metal support layer via adhesive material.

The adhesive material may be a silicone rubber plate or a polyimide adhesive tape.

The forming the build-up layers may include: applying the insulating layers on the both sides of the core substrate as well as in a gap between the electronic component and an inner wall of the cavity; and forming the external circuit layers on the insulating layers.

In the forming the build-up layers, the external circuit layers may include a via connected to an electrode terminal of the electronic component or the internal circuit layers.

The via may be formed using any one selected from among a CNC drill, a CO₂ drill, a laser drill, a Nd-Yag laser drill and a wet etching process.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 7 are cross-sectional views showing a conventional process of manufacturing a printed circuit board including an electronic component embedded therein;

FIG. 8 is a cross-sectional view of a printed circuit board including an electronic component embedded therein, according to an embodiment of the present invention; and

FIGS. 9 to 14 are cross-sectional views sequentially showing a process of manufacturing the printed circuit board including an electronic component embedded therein, according to an embodiment of the present invention.

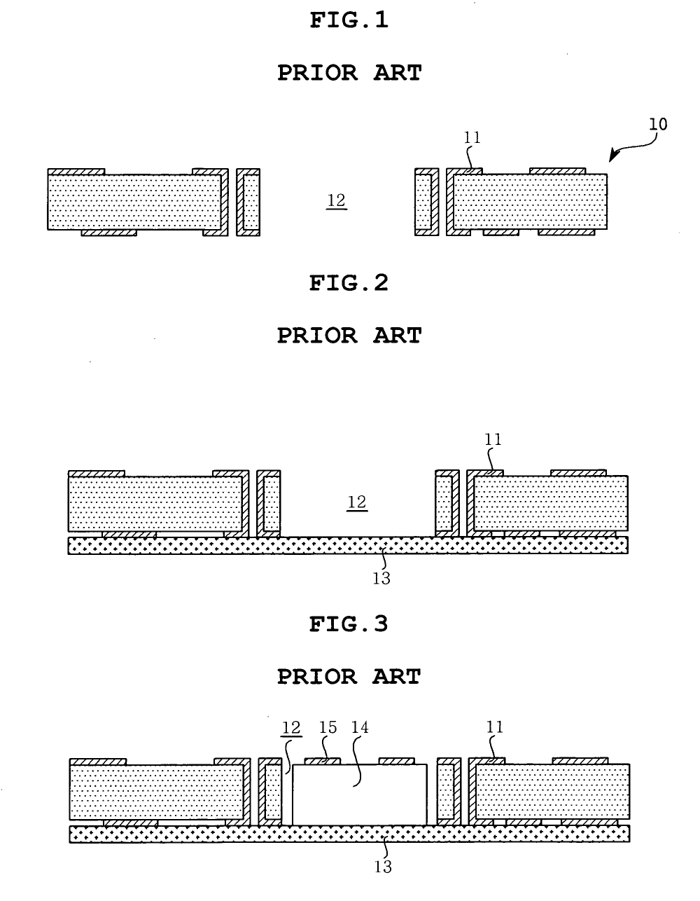

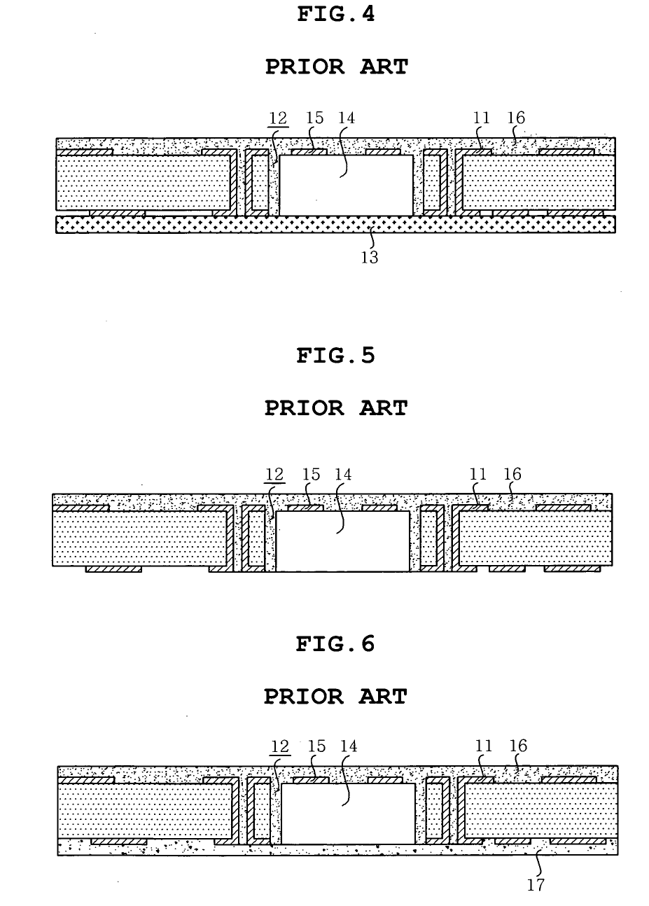

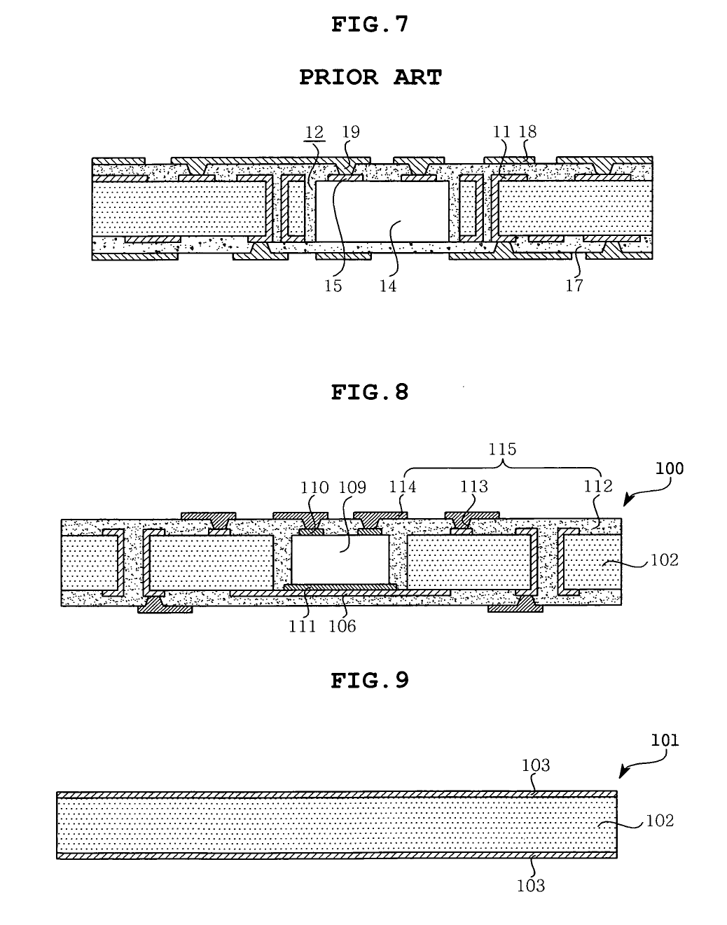

### DESCRIPTION OF THE PREFERRED EMBODIMENTS

Various objects, advantages and features of the invention will become apparent from the following description of embodiments with reference to the accompanying drawings. In the designation of reference numerals, it should be noted that the same reference numerals are used throughout the different drawings to designate the same or similar components. Also, in the description of the present invention, when it is considered that the detailed description of a related prior art may obscure the gist of the present invention, such detailed description is omitted.

Hereinafter, an embodiment of the present invention will be described in greater detail with reference to the following drawings.

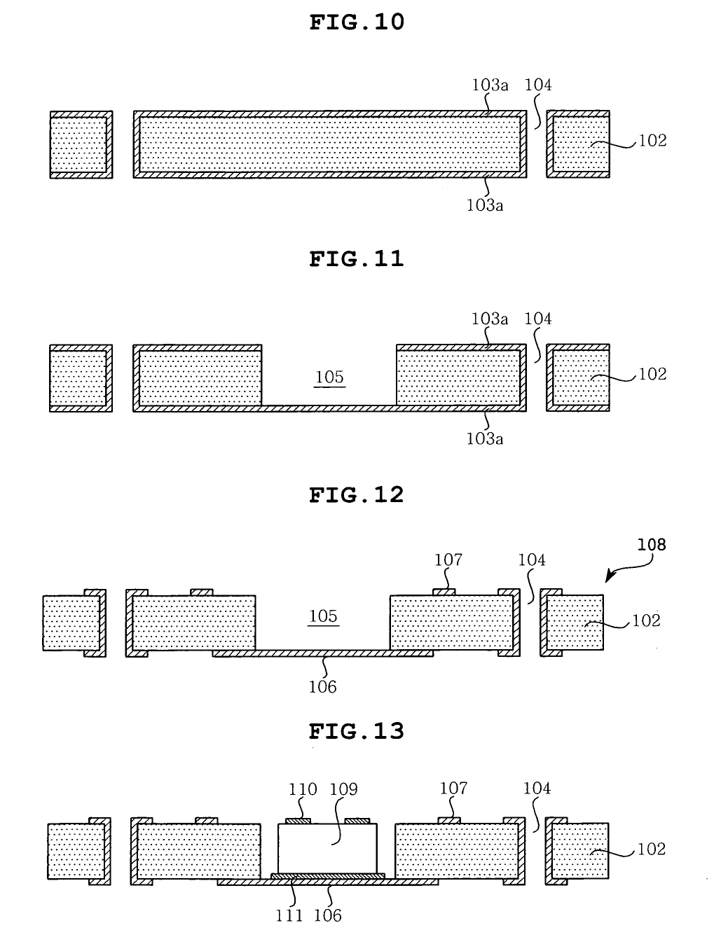

FIG. 8 is a cross-sectional view of a printed circuit board including an electronic component embedded therein, according to an embodiment of the present invention, and FIGS. 9 to 14 are cross-sectional views sequentially showing a process of manufacturing the printed circuit board including an electronic component embedded therein, according to an embodiment of the present invention.

Referring to FIG. 8, the printed circuit board 100 including an electronic component embedded therein, according to an embodiment of the present invention comprises a core substrate 108, an electronic component 109, and build-up layers 115.

The core substrate 108 comprises an insulating resin layer 102, in which a cavity 105 for receiving the electronic component 109 is formed. The insulating resin layer 102 has internal circuit layers 107 placed on the opposite sides thereof, and a through-hole 104 for interconnection between the internal circuit layers 107. Insulating layers 112, in which the cavity 105 is formed, include at one thereof a metal support layer 106 for supporting the electronic component 109 received in the cavity 105.

In this embodiment, the metal support layer 106, which is formed on the one of the insulating layers 112 having the cavity 105 therein, serves as a support for the electronic component 109 as well as a radiator for radiating heat generated from the electronic component 109.

The electronic component 109 is comprised of a semiconductor element, and is provided thereon with electrode terminals 110. The electronic component 109 may be mounted on the metal support layer 106 in a face-up orientation. Furthermore, the electronic component 109 may be fixed on the metal support layer 106 using an adhesive material 111 for reliable fixation.

The build-up layers 115 are formed on both sides of the core substrate 108, and include the insulating layers 112 and external circuit layers 114.

The insulating layers 112 are formed on both sides of the core substrate 114 such that the cavity and a gap between the inner wall of the cavity 105 and the electronic component 109 is filled with the insulating layers 112. The external circuit layers 114 includes vias 113, which are connected to the internal circuit layer 107 or the electrode terminals 110 of the electronic component 109.

FIGS. 9 to 14 are cross-sectional views sequentially showing the process of manufacturing the printed circuit board including an electronic component embedded therein, according to the present invention.

Referring to the drawings, the manufacturing process is now described.

As shown in FIG. 9, a double-sided copper clad laminate 101, which is comprised of insulating layers 102 and copper layers 103 formed on both the insulating layers 102, is prepared.

As shown in FIG. 10, a through-hole 104 is formed in the double-sided copper clad laminate 101, and is then plated.

At this point, the through-hole 104 is perforated using a CNC (Computer Numerical Control) drill or a laser drill (a CO₂ laser drill or a Nd-Yag laser drill). When the through-hole 104 is formed using the CNC drill, a deburring process, which is intended to remove burrs on the copper layers 103, dust on the inner wall of the through-hole 104 and dust on the surfaces of the copper layers 103, generated during the drilling machining, may be conducted. Meanwhile, when the laser drill is used, the through-hole 104 may be formed in a manner such that both the copper layers 103 and the insulating layers 102 are simultaneously drilled at one time using a Yag laser drill, or the portions of the copper layers 103, corresponding to the through-hole 104, are first etched and then the insulating layers 102 are machined using the CO₂ laser drill. After the formation of the through-hole 104, a desmearing process may be conducted.

In the plating of the through-hole 104, because the inner wall of the through-hole 104 is a portion of the insulating layers 102, an electroless copper plated layer is first formed, and then an electrolytic copper plated layer is formed thereon. The copper plated layer is shown in the drawing without differentiation between the electroless copper plated layer and the electrolytic copper plated layer for convenience of explanation. In other words, the electroless copper plated layer and the electrolytic copper plated layer are collectively shown as a single metal layer 103a without differentiation therebetween.

In this process, the electroless copper plating process is conducted using a precipitation effect. For example, the electroless copper plating process may be conducted by execution of a cleanet, soft etching, pre-catalyst treatment, catalyst treatment, acceleration treatment, electroless copper plating or oxidation. The electrolytic copper plating process may be conducted, for example, by immersing a double-sided copper clad laminate 101 in a copper plating bath and then applying current from a DC rectifier thereto.

Subsequently, as shown in FIG. 11, a metal layer 103a formed on one side of the double-sided copper clad laminate and the insulating resin layer 102 are processed at predetermined portions thereof, thus forming a cavity 105 therein.

At this point, the cavity 105 is formed using an etching process or a laser machining process. More specifically, the cavity 105 may be formed in a manner such that the portion of the metal layer 103a, at which the cavity 105 is to be formed, is removed using etching, thus providing a window, and then the corresponding portion of the insulating resin layer 102 is removed using an etching process or a CO₂ laser drill, or the portions of the metal layer 103a and the insulating resin layer 102, at which the cavity 105 is to be formed, are simultaneously removed using a Yag laser drill.

Meanwhile, the metal layer 103a formed on the other side of the double-sided copper clad laminate remains without being removed so as to provide a metal support layer 106 for supporting an electronic component, which is to be mounted later. Referring to FIG. 11, although the portion of the insulating resin layer 102 corresponding to the cavity 105 is shown as being completely removed, the cavity portion of the insulating resin layer 102 may be partially removed to leave a portion thereof, in conformity to the size of the electronic component 109 mounted in the cavity 105, so that the remaining portion of the insulating resin layer 102 supports the electronic component 109. Such modification should also be understood to fall within the scope of the present invention.

Subsequently, as shown in FIG. 12, in order to form the metal support layer 106 for supporting the electronic component, the metal layer 106 is patterned such that the portion of the metal layer corresponding to the cavity 105 is allowed to remain, thereby forming the internal circuit layer 107. As a result, a core substrate 108 is prepared.

At this point, the internal circuit layer 107 and the metal support layer 106 may be formed using a subtractive process, an additive process, or a modified semi-additive process (MSAP), depending on the manufacturing process. In this embodiment, although the internal circuit layer 102 is described as being formed using the subtractive process, the manufacturing method according to the present invention should not be construed to be restricted to the subtractive process.

More specifically, the internal circuit layer 107 is formed in a manner such that a photosensitive photoresist is applied on a metal layer, a photomask is brought into close contact with the photoresist, the photoresist is patterned through light exposure using ultraviolet rays and development, and an unnecessary region of the metal layer is chemically etched by employing the patterned photoresist as an etching resist.

Thereafter, as shown in FIG. 13, the electronic component 109 is inserted into the cavity 105, and is then mounted on the metal support layer 106.

In this regard, the electronic component 109 is attached to a predetermined location while the electronic component 109 is positioned in a face-up orientation.

In the mounting of the electronic component 109, in order to assure highly precise positioning of the electronic component, the electronic component 109 may be attached to the metal support layer 106 using an adhesive material 111 such as adhesive tape.

As the adhesive tape, a silicone rubber plate or polyimide (PI) adhesive tape may be used. Accordingly, by employing the silicone rubber plate having adhesive force or the polyimide adhesive tape, the electronic component 109 can be positioned at a desired location. Furthermore, the adhesive tape may have thermal resistance so as not to be deformed even by heating or pressing in a subsequent process of forming a build-up layer after the electronic component is mounted on the printed circuit board.

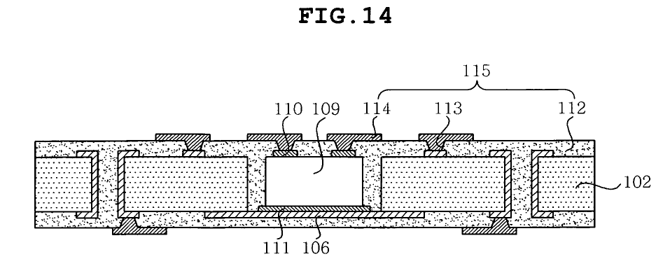

As shown in FIG. 14, build-up layers 115, each of which comprises an insulating layer 112 and an external circuit layer 114, are formed on both sides of the core substrate 108.

At this time, the insulating layers 112, which are prepreg layers in a semi-cured state under pressure, are applied to both sides of the core substrate 108, so that the insulating layers 112 can be applied into the through-hole 104 and a gap between the electronic component 109 and the inner wall of the cavity 105 as well as on both sides of the core substrate 108. Thereafter, external circuit layers 114 are formed on the insulating layers 112 through the additive process or the modified semi-additive process (MSAP).

In this regard, the external circuit layers 114 include vias 113 which are connected to electrode terminals 110 of the electronic components 109 or the internal circuit layer 107. The vias 113 may be formed using any one of a mechanical drill, a laser drill (CO₂ drill or Nd-Yag laser drill) and a wet etching process.

Through the above-described process, a printed circuit board 100 including an electronic component embedded therein, as illustrated in FIG. 8, is prepared.

Although not shown in the drawings, it will be apparent that a multilayer printed circuit board may also be manufactured by providing vias or bumps on both sides of the core substrate 108 including the electronic component 109 therein.

As described above, the printed circuit board including an electronic component embedded therein and a method of manufacturing the printed circuit board according to the present invention has advantages in that since the metal support layer for supporting an electronic component is provided therein, the ability to support the electronic component before and after the manufacturing process is improved, as is the performance of radiating heat generated from the electronic component.

In addition, the printed circuit board including an electronic component embedded therein and a method of manufacturing the printed circuit board, according to the present invention has advantages in that since an electronic component is fixed on a metal support layer, a support tape, which was required heretofore, is obviated, thus reducing production costs, and the manufacturing process is simplified due to the omission of an additional taping process.

Although the preferred embodiment of the present invention has been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A printed circuit board including an electronic component embedded therein, comprising:
a core substrate, which includes an insulating resin layer having a cavity formed therein, a metal support layer formed on one side of the insulating resin layer and internal circuit layers formed on both sides of the insulating resin layer;
an electronic component received in the cavity while being supported on the metal support layer; and
build-up layers, which include insulating layers and external circuit layers formed on both sides of the core substrate.

2. The printed circuit board according to claim 1, wherein the electronic component is mounted in a face-up orientation.

3. The printed circuit board according to claim 1, wherein the electronic component is fixed on the metal support layer using adhesive material.

4. The printed circuit board according to claim 3, wherein the adhesive material is a silicone rubber plate or a polyimide adhesive tape.

5. The printed circuit board according to claim 1, wherein the external circuit layers include vias connected to electrode terminals of the electronic component or the internal circuit layers.

6. A method of manufacturing a printed circuit board including an electronic component embedded therein, comprising:
preparing a core substrate, which includes an insulating resin layer having a cavity formed therein, a metal support layer formed on one side of the insulating resin layer and internal circuit layers formed on both sides of the insulating resin layer;
mounting an electronic component in the cavity such that the electronic component is supported on the metal support layer; and
forming build-up layers, which include insulating layers and external circuit layers, on both sides of the core substrate.

7. The method according to claim 6, wherein the preparing the core substrate comprises:
forming a through-hole in a double-sided copper clad laminate and subjecting the through-hole to metal plating;
removing a portion of the insulating resin layer and a portion of a metal layer formed on one side of the insulating resin layer, thus forming the cavity; and
patterning the metal layer while leaving a metal layer formed on the other side of the insulating resin layer, thus forming the metal support layer and the internal circuit layers.

8. The method according to claim 6, wherein in the mounting the electronic component, the electronic component is mounted in a face-up orientation.

9. The method according to claim 6, wherein in the mounting the electronic component, the electronic component is fixed on the metal support layer via adhesive material.

10. The method according to claim 9, wherein the adhesive material is a silicone rubber plate or a polyimide adhesive tape.

11. The method according to claim 6, wherein the forming the build-up layers comprises:
applying the insulating layers on the both sides of the core substrate as well as in a gap between the electronic component and an inner wall of the cavity; and
forming the external circuit layers on the insulating layers.

12. The method according to claim 6, wherein in the forming the build-up layers, the external circuit layers include a via connected to an electrode terminal of the electronic component or the internal circuit layers.

13. The method according to claim 12, wherein the via is formed using any one selected from among a CNC drill, a CO₂ drill, a laser drill, a Nd-Yag laser drill and a wet etching process.
